(19) United States
(12) Patent Application Publication
(10) Pub. No.: US 2006/0276014 A1
(43) Pub. Date: Dec. 7, 2006

(54) Self-aligned high-energy implantation for deep junction structure

(75) Inventors: Tzu-Hsuan Hsu, Kaohsiung (TW); Dun-Nian Yaung, Taipei (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/146,033

(22) Filed: Jun. 7, 2005

(51) Int. Cl. H01L 21/425; H01L 21/22

(52) U.S. Cl. 438/526; 438/551

(57) ABSTRACT

A self-aligned high-energy implantation process of forming a deep junction structure. For exposing a predetermined region of a semiconductor substrate, a masking structure has a gate layer, a hard mask layer patterned on the gate layer, and a photoresist layer covering parts of said semiconductor substrate, said gate layer and said hard mask layer. The hard mask layer has a thickness greater than 350 Angstroms. Using the masking structure and performing an ion implantation process requiring an energy greater than 70 keV, a doped region of a second conductive type is formed in the predetermined region of the semiconductor substrate of a first conductive type.

### TECHNICAL FIELD

The present invention relates to a semiconductor device process, and particularly to a self-aligned high-energy implantation process for fabricating a deep junction structure in a semiconductor substrate.

### BACKGROUND

High-energy implantation is an important technology in forming doped layers, either deeply in the substrate or through thick overlying layers into the substrate. In CMOS image sensor technology for VLSI applications, high-energy implantation is a key process to form a deep junction structure between p-type and n-type diffusion profiles currently used as photodiode regions. High-energy implantation also offers an advantage of forming n-well or p-well after high temperature step for field oxidation, thus lateral diffusion is strongly suppressed to reduce necessary well layout. High-energy implantation can also be used to replace conventional buried layers in RAM or ROM cells, for example a storage-node junction region in SRAM or DRAM cell.

Alignment control of high-energy implantation is getting important as the device size is shrinking to next-generation dimension. In some conventional semiconductor devices, a deep junction region either aligned to a gate structure or an isolation structure is defined by a thick photoresist in a non-self-aligned manner prior to the formation of a polysilicon gate structure. Such methods can make it difficult to control the width and the distance, and misalignment during high-energy implantation might decrease reliability of the device. In addition, the higher the implant energy, the faster the photoresist erodes. In some conventional semiconductor devices, a polysilicon-gate mask is employed to reduce costs associated with the manufacturing of the device. However, the polysilicon-gate mask fails in relative high-energy implantation requiring energies greater than 40 keV and up to several MeV, because the dopant might pass through the polysilicon-gate mask to influence the device performance, such as channel length, which consequently enlarges device size and reduces transistor density. This problem will become worse as the thickness of the polysilicon gate layer is decreasing to meet with requirements of the scale-down device.

### SUMMARY OF THE INVENTION

Embodiments of the present invention provide self-aligned high-energy implantation for defining deep junction structures to produce both uniform electrical characteristics across wafers and enhanced device performance.

In one aspect, the present invention provides a masking structure has a gate layer, a hard mask layer patterned on the gate layer, and a photoresist layer covering parts of said semiconductor substrate, said gate layer and said hard mask layer in order to expose a predetermined region of a semiconductor substrate of a first conductive type. The hard mask layer has a thickness greater than 350 Angstroms. Using the masking structure and performing an ion implantation process requiring an energy greater than 70 keV, a doped region of a second conductive type is formed in the predetermined region of the semiconductor substrate of a first conductive type.

In another aspect, the present invention provides a masking structure has a gate layer, a hard mask layer patterned on the gate layer, and a photoresist layer covering parts of said semiconductor substrate, said gate layer and said hard mask layer in order to expose a predetermined photosensitive region of an image sensor cell on a semiconductor substrate. The hard mask layer has a thickness greater than 350 Angstroms. Using the masking structure and performing an ion implantation process requiring an energy greater than 70 keV, a doped region is formed in the predetermined photosensitive region of an image sensor cell.

In another aspect, the present invention provides a masking structure has a gate layer, a hard mask layer patterned on the gate layer, and a photoresist layer covering parts of said semiconductor substrate, said gate layer and said hard mask layer in order to expose a predetermined storage node region of a memory cell on a semiconductor substrate. The hard mask layer has a thickness greater than 350 Angstroms. Using the masking structure and performing an ion implantation process requiring an energy greater than 70 keV, a doped region is formed in the predetermined storage node region of a memory cell.

### BRIEF DESCRIPTION OF THE DRAWINGS

The aforementioned objects, features and advantages of this invention will become apparent by referring to the following detailed description of the preferred embodiments with reference to the accompanying drawings, wherein:

FIG. 1A and FIG. 1B are cross-sectional diagrams illustrating an exemplary embodiment of self-aligned high-energy implantation for forming a deep junction structure;

FIG. 2 is a cross-sectional diagram illustrating an exemplary embodiment of self-aligned high-energy implantation for forming a deep n-well of a pinned photodiode; and

FIG. 3 is a cross-sectional diagram illustrating an exemplary embodiment of an exemplary embodiment of self-aligned high-energy implantation for forming a double diffused source region in a modified photodiode underneath trench isolation.

### DETAILED DESCRIPTION OF ILLUSTRATIVE EMBODIMENTS

Embodiments of the present invention provide self-aligned high-energy implantation for defining deep junction structures to produce both uniform electrical characteristics across wafers and enhanced device performance. Particularly, embodiments of the present invention provide a masking structure, including a gate layer, a thick hard mask and a patterned photoresist layer, to define a doped region self-aligned to the gate layer, which overcomes the aforementioned problems of the prior art arising from the use of thick photoresist mask or single polysilicon mask. This self-aligned high-energy implantation enables a manufacturer to more easily control and enables a manufacturer to reduce the number of masking steps, which leads to a reduction in time and costs associated with the manufacturing of the device. In the masking structure, the thick hard mask provided on the gate layer requires a desired thickness to prevent dopants from passing through the polysilicon gate so as to well control lateral diffusion phenomenon across wafers. The thick hard mask also acts an anti-reflective layer for photolithography at gate masking, thus the thickness control of the thick hard mask is further contemplated in order to maintain the substrate reflectivity for good photo performance. Any hard mask material having high etching selectivity with respect to the materials (e.g., silicon oxide, silicon-based material, silicon nitride, or the like) surrounding it will advantageously be used to form the thick hard mask for averting damages to gate oxide, silicon substrate or gate sidewall spacer during subsequent removal of the thick hard mask.

As used throughout this disclosure, the term “high-energy implantation” refers to an ion implantation process requiring implant energy greater than 70 keV and results in ion doped profiles in a semiconductor substrate. The term “deep junction structure” refers to a junction region deeply formed in a semiconductor substrate, such as a deep PN junction formed between an n-type region (n-well) and a p-type region (p-well or p-type substrate), which is adapted for use in a wide variety of applications including pinned photodiode, CMOS image sensor, light sensing device, SRAM cell, DRAM cell, RAM or ROM cell, and the like. Reference will now be made in detail to the present embodiments, examples of which are illustrated in the accompanying drawings. Wherever possible, the same reference numbers are used in the drawings and the description to refer to the same or like parts. In the drawings, the shape and thickness of one embodiment may be exaggerated for clarity and convenience. This description will be directed in particular to elements forming part of, or cooperating more directly with, apparatus in accordance with the present invention. It is to be understood that elements not specifically shown or described may take various forms well known to those skilled in the art. Further, when a layer is referred to as being on another layer or “on” a substrate, it may be directly on the other layer or on the substrate, or intervening layers may also be present.

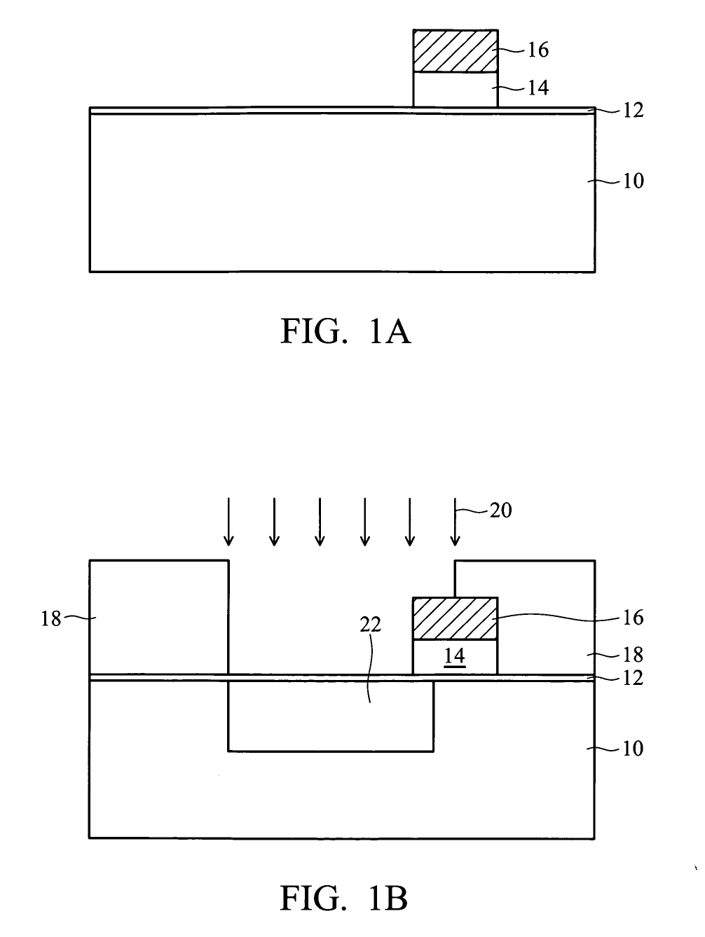

Herein, cross-sectional diagrams of FIG. 1A and FIG. 1B illustrate an exemplary embodiment of self-aligned high-energy implantation for forming a deep junction structure. An example of a substrate 10 may comprise an elementary semiconductor such as silicon, germanium, and diamond, or a compound semiconductor such as silicon carbide, gallium arsenic, indium arsenide, and indium phosphide. The substrate 10 may have a single-crystal structure and the substrate surface may have a proper orientation, for example, a top surface oriented in (100), (110), or (111). The substrate 10 may include an epitaxial layer overlying a bulk semiconductor, a silicon germanium layer overlying a bulk silicon, a silicon layer overlying a bulk silicon germanium, or a semiconductor-on-insulator (SOI) structure. The substrate 10 may comprise a p-type doped region and/or an n-type doped region, which may be implemented by a process such as ion implantation. The substrate 10 may comprise an isolation feature to separate different devices formed thereon. The isolation feature may comprise different structure and can be formed using different processing technologies. For example, the isolation feature may comprise a dielectric isolation such as local oxidation of silicon (LOCOS), shallow trench isolation (STI), junction isolation, field isolation, and/or other suitable isolation structures.

A gate dielectric layer 12 is formed on an active area of the substrate 10. In one embodiment, the gate dielectric layer 12 is a silicon oxide layer with a thickness chosen specifically for the scaling requirements of the MOSFET device technology, for example, formed through a thermal oxidation process or a chemical vapor deposition (CVD) process. It is to be appreciated other well-known gate dielectric material such as oxides, nitrides, high-k materials, and combinations thereof. At least one gate structure is formed on the gate dielectric layer 12 within the active area through advances in deposition, lithography and masking techniques and dry etching processes. As depicted in FIG. 1A, a gate material and a hard mask material are successively deposited and then patterned to form a gate layer 14 stacked by a hard mask layer 16. The patterning step may be accomplished using photolithography and etching to transfer the pattern defined by a photomask to the hard mask layer 16 and the gate layer 14. The photolithography process may include photoresist coating, soft baking, mask aligning, exposing, post-exposure baking, developing photoresist, hard baking, and photoresist stripping. The etching process may include wet etch, dry etch, ion-reactive-etch (RIE), and other suitable processing. A cleaning process may be followed after patterning the gate structure. In one embodiment, the gate layer 14 is a polysilicon layer with a gate length chosen specifically for the scaling requirements of the MOSFET device technology, for example deposited through Low Pressure CVD (LPCVD) methods, CVD methods and Physical Vapor Deposition (PVD) sputtering methods employing suitable silicon source materials. If desired the polysilicon layer may be ion implanted to the desired conductive type. It is to be appreciated other well-known gate electrode material such as metal, metal alloys, single crystalline silicon, or any combinations thereof.

For photolithography at gate masking, the hard mask layer 16 acts a bottom anti-reflective layer underneath the photoresist, thus the material choice and thickness control of the hard mask layer 16 are tight in order to maintain the substrate reflectivity for good photo performance. However, the hard mask layer 16 also acts as a thick hard mask for subsequent high-energy implantation, thus the thickness control of the hard mask layer 16 should be further contemplated to prevent the penetration of dopants. Considering subsequent removal of the hard mask layer 16, the material choice of the hard mask layer 16 should be further contemplated to avert damages to the gate dielectric layer 12 or the substrate 10. In some embodiments, oxynitride, silicon oxynitride (SiON) or any other SiON-based materials may be used to form the hard mask layer 16 by a method such as chemical vapor deposition (CVD), physical vapor deposition (PVD), or atomic layer deposition (ALD). SiON-based materials are advantageously used since its etching rate may be up to one hundred and fifty times greater than that of silicon dioxide and seven times that of silicon nitride in liquid etching and forty times that of silicon dioxide in plasma etching. In some embodiments, other hard mask material having high etching selectivity with respect to the materials (e.g., silicon oxide, silicon-based material, silicon nitride) surrounding it will advantageously be used to form the hard mask layer 16 for averting damages to the gate dielectric layer 12, the substrate 10 or gate sidewall spacer during subsequent removal of the hard mask layer 16. The hard mask material having a high etching rate with respect to silicon dioxide in an etch solution including hydrofluoric acid (HF) and phosphoric acid (H₃PO₄) will advantageously be used to form the hard mask layer 16. For example, during subsequent removal of the hard mask layer 16 in the HF and H₃PO₄ solution, a gate oxide layer of 50 Angstroms will be partially etched, leaving the gate oxide layer of more than 9˜10 Angstroms on the substrate. The thickness of the hard mask layer 16 is chosen specifically for the reflectivity requirements of the photolithography technology and reaches a level sufficient to obstruct penetration of implanted dopants. For example, the hard mask layer 16 may have a thickness greater than 350 Angstroms. Depending on the reflectivity requirements, the hard mask layer 16 may have a thickness varying from about 350 Angstroms to about 500 Angstroms in some embodiments, the hard mask layer 16 may have a thickness varying from about 800 Angstroms to about 900 Angstroms in some embodiments, and the hard mask layer 16 may have a thickness varying from about 2000 Angstroms to about 2500 Angstroms in some embodiments.

Referring to FIG. 1B, a patterned photoresist layer 18 is provided to cover portions of the hard mask layer 16, the gate layer 14 and the substrate 10, thus exposing a predetermined area of the substrate 10 for subsequent high-energy implantation. The patterning process for the photoresist layer 18 may include photoresist coating, soft baking, mask aligning, exposing, post-exposure baking, developing photoresist and hard baking. The predetermined area may refer to a photosensitive region of an image sensor cell, a storage node region of a memory cell, or the like. In some embodiments, the patterned photoresist layer 18 may be designed to expose a portion of the gate layer 14 and the hard mask layer 16. A high-energy implantation masking structure of the present invention, consisting of the patterned photoresist layer 18, the hard mask layer 16 and the gate layer 14, is therefore completed.

A high-energy implantation process 20, for example a vertical implantation or a tilted-angle implantation, is then performed to form a doping region 22 in the substrate 10. In this self-aligned manner of using the high-energy implantation mask including the layers 14, 16 and 18, the doping region 22 is self-aligned to the gate layer 14 and might laterally extend to an edge of the gate layer 14. Since the hard mask layer 16 is thick enough to prevent dopants from passing through the gate layer 14, the self-aligned high-energy implantation of the present invention can produce both uniform electrical characteristics across wafers and enhanced device performance. The high-energy implantation process 20 is preferably performed using a relatively large energy greater than about 70 keV (e.g., 80 keV, 160 keV, 460 keV) and a dose of between about 1E13 ions/cm² and about 1E15 ions/cm². This implantation process 20 forms the doped region 22 with a conductive type counter to a region surrounding it in the substrate 10 and a depth substantially deeper than subsequently formed source/drain regions, thus creating a deep junction structure in the substrate 10. For example, when the substrate 10 is a p-type substrate, the doped region 22 is fabricated as an n-well to form a deep PN junction there between. Depending on the thickness requirements for obstructing dopant penetration, the hard mask layer 16 may have a thickness of about 350 Angstroms to about 2500 Angstroms as the energy level of the implantation process 20 varies from 80 keV to 460 keV or above. In one embodiment, the hard mask layer 16 may have a thickness not less than about 400 Angstroms when the implantation process 20 is performed at energy of about 80 keV. In one embodiment, the hard mask layer 16 may have a thickness not less than about 800 Angstroms when the implantation process 20 is performed at energy of about 160 keV. In one embodiment, the hard mask layer 16 may have a thickness not less than about 2000 Angstroms when the implantation process 20 is performed at energy of about 460 keV. In some embodiments, the high-energy implantation process 20 is performed, at an energy level within the range of 100 keV to 200 keV, to form the doped region 22 as a storage node region of a memory cell. After the implantation process 20, the patterned photoresist layer 18 will be stripped off The hard mask layer 16 will then be removed from the gate layer 14 in order to proceed with semiconductor processes. For example, a wet etching process using HF and H₃PO₄ solution may be performed to remove the SiON-based material. In this step, an exemplary gate oxide layer of 50 Angstroms will be partially etched, leaving the gate oxide layer of more than 9˜10 Angstroms on the substrate.

The self-aligned high-energy implantation of the present invention may be used in imager applications incorporated with various designs. The semiconductor industry currently uses different types of semiconductor-based imagers, such as photodiode arrays of CMOS imagers. A CMOS imager circuit includes an array of pixel cells, each pixel cell including either a photodiode, a photo gate or a photoconductor overlying a doped region of a substrate for accumulating photo-generated charge in the underlying portion of the substrate. A readout circuit is connected to each pixel cell and includes a charge transfer section formed on the substrate adjacent the photodiode, photo gate or photoconductor having a sensing node, typically a floating diffusion node, connected to the gate of a source follower output transistor. The imager may include at least one transistor for transferring charge from the charge accumulation region of the substrate to the floating diffusion node and also has a transistor for resetting the diffusion node to a predetermined charge level prior to charge transference.

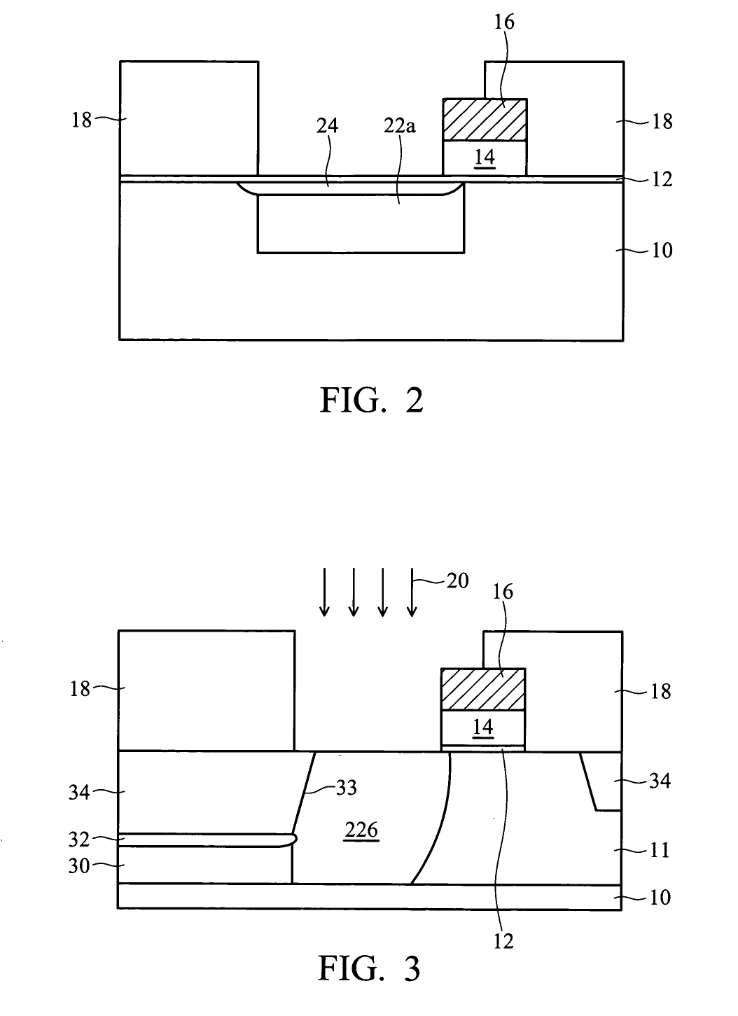

The self-aligned high-energy implantation of the present invention for some exemplary photodiodes is described now. A cross-sectional diagram of FIG. 2 illustrates an exemplary embodiment of self-aligned high-energy implantation for forming a deep n-well of a pinned photodiode. Explanation of the same or similar portions to the description in FIG. 1A and FIG. 1B is omitted herein. Using a p-type substrate 10 as an example, the high-energy implantation process 20 may employ n-type dopants, such as arsenic, antimony, or phosphorous to form a deep n-well 22a self-aligned to the gate layer 14 in a photosensitive area of a pixel cell, forming a deep PN junction. The deep n-well 22a forms a photosensitive charge storage region for collecting photo-generated electrons. Before removing the patterned photoresist layer 18 and the hard mask layer 16, another implantation process may be performed to form a p-type region 24 into the substrate 10 over the n-well 22a and adjacent to the gate layer 14, thus creating a p-type pinned surface layer (e.g., p⁺-type pinning region). The potential in the photodiode is pinned to a constant value when the photodiode is fully depleted. The electron capacity of pinned photodiodes typically depends on the doping level of the image sensor and the dopants implanted into the active layer. This p-n-p structure is formed as a pinned photodiode within the substrate 10. While the embodiment is directed to a p-n-p pinned photodiode structure, the embodiments also are applicable to an n-p-n pinned photodiode structure.

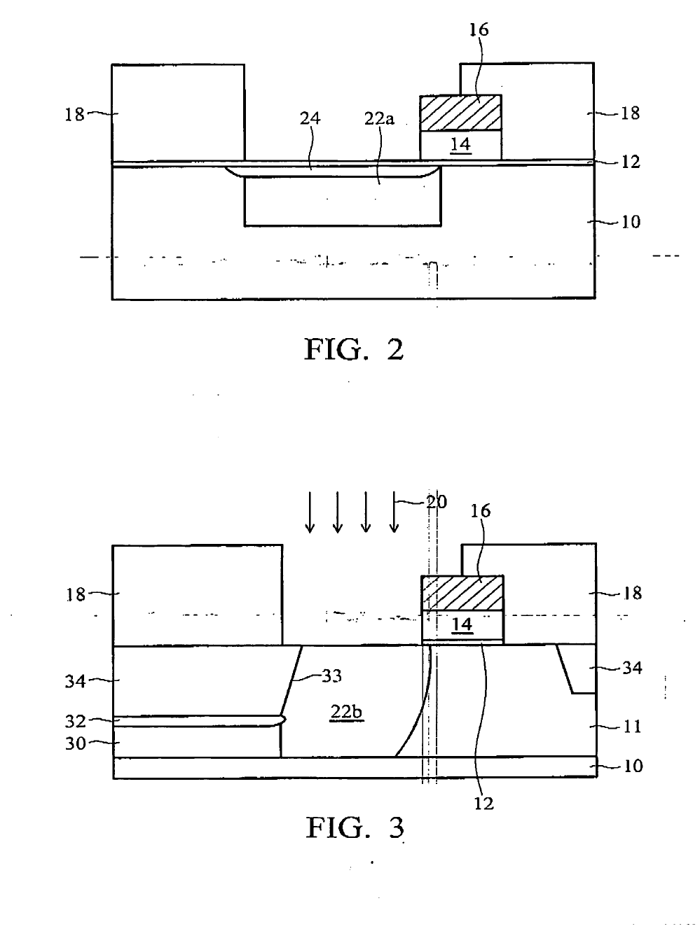

A cross-sectional diagram of FIG. 3 illustrates an exemplary embodiment of self-aligned high-energy implantation for forming a double diffused source (DDS) region in a modified photodiode underneath trench isolation. The DDS region is fabricated under a source region of a reset transistor, and this source region will be coupled to a terminal of the photodiode to form a floating node for each pixel. Explanation of the same or similar portions to the description in FIG. 1A and FIG. 1B is omitted herein. An exemplary p-type substrate 10 comprises isolation structures 34 for defining element-to-element active areas. In one embodiment, the isolation structure 34 employs a shallow trench isolation (STI) structure, which may be created with well-known approaches, including steps of etching trenches 33 into the substrate 10, depositing isolating materials (oxide, nitride or combinations thereof) into the trenches 33, polishing off the excess isolating materials, and planarizing the isolation features for the next level of fabrication. In some embodiments, after depositing isolating materials in the trenches 33, photolithography process and ion implantation process are performed to form a lightly doped n-type region 30 underneath the isolation structure 34 in the substrate 10, and then form a heavily doped p-type region 32 underneath the isolation structure 34 and over the n-type region 30. In some embodiments, before depositing isolating materials in the trenches 33, the n-type region 30 and the p-type region 32 are successively fabricated underneath the trench 33. A PNP pinned photodiode is therefore fabricated underneath the isolation structure 34. Next, another photolithography process and ion implantation process are performed to form a p-well 11 that is used for the formation of the n-channel transistors in pixel cell. The gate dielectric layer 12, the polysilicon gate layer 14 and the hard mask layer 16 are then patterned on the p-well 11 by methods described in FIG. 1A and FIG. 1B. The gate layer 14 may be used for a reset transistor in a CMOS image sensor.

In order to form a double diffused source (DDS) region under a source region, a patterned photoresist layer 18 is provided to expose a predetermined region of the p-well 11, thus the layers 18, 16 and 14 can serve as the mask for subsequent self-aligned high-energy implantation. The high-energy implantation process 20 is next performed using a relatively large energy of greater than about 70 KeV (e.g., 80 keV, 130 keV, 460 keV) and a dose of between about 3×10¹³ ions/cm² and about 5×10¹⁴ ions/cm², to form a heavily doped region 22b, counter-doped to the p-well 11, at the source of the reset transistor. The region 22b is substantially deeper than a source region that will be formed laterally adjacent to the gate layer 14 in subsequent processes. In this case, the region 22b serving as a DDS region for the reset transistors in the pixel is a heavily doped n-type region. The DDS region is substantially deeper than the location of the STI defects to thereby correct the leakage effect.

Although the present invention has been described in its preferred embodiments, it is not intended to limit the invention to the precise embodiments disclosed herein. Those skilled in this technology can still make various alterations and modifications without departing from the scope and spirit of this invention. Therefore, the scope of the present invention shall be defined and protected by the following claims and their equivalents.

1. A process of forming a deep junction structure, comprising:
providing a semiconductor substrate of a first conductivity type;
forming a masking structure on said semiconductor substrate to expose a predetermined region of said semiconductor substrate, said masking structure comprising a gate layer, a hard mask layer patterned on said gate layer, and a photoresist layer converting parts of said semiconductor substrate, said gate layer and said hard mask layer, wherein said hard mask layer has a thickness grater than 350 Angstroms; and
using said masking structure and performing an ion implantation process requiring an energy greater than 70 keV to form a doped region of a second conductive type in said predetermined region of said semiconductor substrate.

2. The process of claim 1, wherein said doped region is used as a photosensitive region of an image sensor cell.

3. The process of claim 1, wherein said doped region is used as a storage node region of a memory cell.

4. The process of claim 1, wherein said predetermined region of said semiconductor substrate is adjacent to said gate layer, and said doped region is self-aligned to said gate layer.

5. The process of claim 1, wherein said gate layer comprises polysilicon.

6. The process of claim 1, wherein said hard mask layer comprises silicon oxynitride (SiON) or SiON-based materials.

7. The process of claim 1, wherein said hard mask layer acts as an anti-reflective layer for patterning said gate layer.

8. The process of claim 1, wherein said hard mask layer has a thickness from about 350 Angstroms to 500 Angstroms.

9. The process of claim 1, wherein said hard mask layer has a thickness from about 800 Angstroms to 900 Angstroms.

10. The process of claim 1, wherein said hard mask layer has a thickness from about 2000 Angstroms to 2500 Angstroms.

11. A process of forming a photosensitive region of an image sensor cell, comprising:
providing a semiconductor substrate of a first conductivity type;
forming a gate dielectric layer on said semiconductor substrate;
forming a gate layer stacked by a hard mask layer on said gate dielectric layer, wherein said hard mask layer acts as an anti-reflective layer for patterning said gate layer, said hard mask layer has a thickness greater than 350 Angstroms;
forming a photoresist layer covering parts of said semiconductor substrate, said gate layer and said hard mask layer to expose a predetermined photosensitive region of said semiconductor substrate, and
performing an ion implantation process requiring an energy greater than 70 keV to form a doped region of a second conductive type in said predetermined photosensitive region of said semiconductor substrate.

12. The process of claim 11, wherein said predetermined region of said semiconductor substrate is adjacent to said gate layer, and said doped region is self-aligned to said gate layer.

13. The process of claim 11, wherein said gate layer comprises polysilicon.

14. The process of claim 11, wherein said hard mask layer comprises silicon oxynitride (SiON) or SiON-based materials.

15. The process of claim 11, wherein said hard mask layer has a thickness from about 350 Angstroms to about 500 Angstroms.

16. The process of claim 11, wherein said hard mask layer has a thickness from about 800 Angstroms to about 900 Angstroms.

17. The process of claim 11, wherein said hard mask layer has a thickness from about 2000 Angstroms to about 2500 Angstroms.

18. A process of forming a storage node region of a memory cell, comprising:
providing a semiconductor substrate of a first conductivity type;
forming a gate dielectric layer on said semiconductor substrate;
forming a gate layer stacked by a hard mask layer on said gate dielectric layer, wherein said hard mask layer acts as an anti-reflective layer for patterning said gate layer, said hard mask layer has a thickness greater than 350 Angstroms;
forming a photoresist layer covering parts of said semiconductor substrate, said gate layer and said hard mask layer to expose a predetermined storage node region of said semiconductor substrate, and
performing an ion implantation process requiring an energy greater than 70 keV to form a doped region of a second conductive type in said predetermined storage node region of said semiconductor substrate.

19. The process of claim 18, wherein said predetermined storage node region of said semiconductor substrate is adjacent to said gate layer, and said doped region is self-aligned to said gate layer.

20. The process of claim 18, wherein said hard mask layer comprises silicon oxynitride (SiON) or SiON-based materials.
